(19) United States
(12) Patent Application Publication
(10) Pub. No.: US 2008/0131998 A1
(43) Pub. Date: Jun. 5, 2008

(54) Method of fabricating a film-on-wire bond semiconductor device

(76) Inventors: Hem Takiar, Fremont, CA (US); Shrikar Bhagath, San Jose, CA (US); Chin-Tien Chiu, Taichung City (TW); Ong King Hoo, Shanghai (CN)

Correspondence Address: VIERRA MAGEN/SANDISK CORPORATION, 575 MARKET STREET, SUITE 2500, SAN FRANCISCO, CA, 94105, US

(21) Appl. No.: 11/566,097

(22) Filed: Dec. 1, 2006

(51) Int. Cl. H01L 21/768

(52) U.S. Cl. 438/109; 257/E21.575

(57) ABSTRACT

A low profile semiconductor package is disclosed including at least first and second stacked semiconductor die mounted to a substrate. The first and second semiconductor die are separated by a low profile intermediate adhesive layer in which the wire bond loops from the first semiconductor die are embedded. After the intermediate layer is applied, the second semiconductor die may be stacked on top of the intermediate layer. A dielectric layer may be formed on a back surface of the second semiconductor die. As the back side of the second semiconductor die is an electrical insulator, the intermediate layer need not space the wire bond loops from the second semiconductor die as in the prior art, and the apex of bond wires may come into contact with the dielectric layer. The intermediate layer may thus be made thinner in comparison to conventional stacked semiconductor die configurations.

### BACKGROUND OF THE INVENTION

1. Field of the Invention

Embodiments of the present invention relate to a low profile semiconductor device and method of fabricating same.

2. Description of the Related Art

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

While a wide variety of packaging configurations are known, flash memory storage cards may in general be fabricated as system-in-a-package (SiP) or multichip modules (MCM), where a plurality of die are mounted on a substrate. The substrate may in general include a rigid, dielectric base having a conductive layer etched on one or both sides. Electrical connections are formed between the die and the conductive layer(s), and the conductive layer(s) provide an electric lead structure for connection of the die to a host device. Once electrical connections between the die and substrate are made, the assembly is then typically encased in a molding compound to provide a protective package.

A cross-section of a conventional semiconductor package 18 (without molding compound) is shown in FIG. 1. Typical packages include a plurality of semiconductor die. The die may be affixed to the substrate via die attach adhesive layer 24. Generally, the substrate 22 is formed of a rigid core 28, of for example polyimide laminate. Thin film copper layer(s) 30 may be formed on the core in a desired electrical lead pattern using known photolithography and etching processes. Exposed surfaces of the conductance pattern may be plated for example with one or more layers of gold in a plating process to form contact pads for electrical connection of the semiconductor die to the substrate and electrical connection of the substrate to a host device. The substrate may be coated with a solder mask 36, leaving the contact pads exposed, to insulate and protect the electrical lead pattern formed on the substrate. Bond pads on the semiconductor die may be electrically connected to the plated contact pads on the substrate by wire bonds 34.

It is known to layer semiconductor die on top of each other either with an offset or in a stacked configuration. In an offset configuration, a die is stacked on top of another die so that the bond pads of the lower die are left exposed. An offset configuration provides an advantage of convenient access of the bond pads on each of the semiconductor die. However, the offset requires a greater footprint on the substrate, where space is at a premium.

In stacked configurations, such as that shown in prior art FIG. 1, two or more semiconductor die are stacked directly on top of each other, thereby taking up less footprint on the substrate as compared to an offset configuration. However, in a stacked configuration, space must be provided between adjacent semiconductor die for the bond wires 34. In addition to the height of the bond wires 34 themselves, additional space must be left above the bond wires, as contact of the bond wires 34 of one die with the next die above may result in an electrical short. As shown in FIG. 1 and the enlarged view of FIG. 2, it is therefore known to bury the wire bond loops between two adjacent semiconductor die within the adhesive layer 26 between the respective die. Such configurations are shown for example in U.S. Pat. No. 6,388,313 to Lee et al., entitled, “Multi-Chip Module,” and U.S. Pat. No. 7,037,756 to Jiang et al., entitled, “Stacked Microelectronic Devices and Methods of Fabricating Same.” These references disclose semiconductor die packages as in prior art FIGS. 1 and 2 of the present invention where wire bond loops 34 are buried within an adhesive layer 26 having a sufficient thickness to prevent shorting of the wire bond loops against the lower surface of the upper die 20.

There is an ever-present drive to increase storage capacity within memory modules. One method of increasing storage capacity is to increase the number of memory die used within the package. In portable memory packages, the number of die which may be used is limited by the thickness of the package. There is accordingly a keen interest in decreasing the thickness of the contents of a package while increasing memory density. The package 18 shown in FIGS. 1 and 2 requires the adhesive layer 26 separating the semiconductor die to be thicker than is otherwise necessary so as to ensure that the wire bond loops remain buried and do not contact the underside of the next adjacent semiconductor die during fabrication. This additional thickness of the adhesive layer becomes even more of a problem in packages having more than two stacked die and multiple layers of adhesive having embedded wire bond loops.

### SUMMARY OF THE INVENTION

An embodiment of the present invention relates to a low profile semiconductor package including at least first and second stacked semiconductor die mounted to a substrate. The first and second semiconductor die are separated by a low profile intermediate layer in which the wire bond loops between the first semiconductor die and substrate are embedded. The intermediate layer may be an electrically insulative epoxy applied as a viscous liquid onto the first semiconductor die. The intermediate layer may be applied over at least substantially the entire surface of the first semiconductor die, or only in discrete quantities over the bond pads of the first semiconductor die.

After the intermediate layer is applied, the second semiconductor die may be stacked on top of the intermediate layer. In accordance with the present invention, a dielectric layer may be formed at the interface between the second semiconductor die and intermediate layer. In embodiments, the dielectric layer may be formed on a back surface of the second semiconductor die by any of a variety of known methods, such as for example laminating an epoxy, or growing or depositing a dielectric film during the fabrication of the semiconductor wafer from which the second semiconductor die is taken. In instances where a wafer is background to bring it to a desired thickness, the dielectric layer can be formed after the backgrind process and prior to assembly onto the first semiconductor die.

As the back side of the second semiconductor die is an electrical insulator, the intermediate layer need not space the wire bond loops from the second semiconductor die as in the prior art, and the apex of bond wires may come into contact with the dielectric layer. The spacing between the first and second stacked semiconductor die may thus be made thinner in comparison to conventional stacked semiconductor die configurations. The second semiconductor die may further be affixed under a compressive load so as to reduce a thickness of the intermediate layer, as well as partially flattening the height of the bond wires above the surface of the first semiconductor die.

Once all semiconductor die are affixed and wire bonded to the substrate, the semiconductor package may be cured, including for example by heating and/or by ultraviolet radiation. In an alternative embodiment, the intermediate layer may be cured before the second semiconductor die is affixed thereto.

### DESCRIPTION OF THE DRAWINGS

FIG. 1 is a cross sectional side view of a portion of a conventional semiconductor package including stacked semiconductor die mounted on a substrate.

FIG. 2 is an enlarged cross sectional side view of a portion of the semiconductor package shown in FIG. 1.

FIG. 3A is a flowchart of the fabrication of the semiconductor package according to an embodiment of the present invention.

FIG. 3B is a flowchart of the fabrication of the semiconductor package according to an alternative embodiment of the present invention.

FIG. 4 is a cross sectional side view of a portion of the semiconductor package of the present invention during fabrication.

FIG. 5 is a top view of the portion of the semiconductor package of the present invention shown in FIG. 4.

FIG. 6 is a cross sectional side view of a portion of the semiconductor package of the present invention during fabrication.

FIG. 7 is a cross sectional side view of a portion of the semiconductor package of the present invention during fabrication.

FIG. 8 is a cross sectional side view of a portion of the semiconductor package of an alternative embodiment of the present invention during fabrication.

FIG. 9 is a cross sectional side view of a portion of the semiconductor package of a further alternative embodiment of the present invention during fabrication.

FIG. 10 is a top view of a portion of the semiconductor package of the alternative embodiment shown in FIG. 9.

FIG. 11 is a cross sectional side view of a portion of the semiconductor package shown in FIG. 9 during fabrication.

FIG. 12 is a cross sectional side view of a portion of the semiconductor package shown in FIG. 9 during fabrication.

FIG. 13 is a cross sectional side view of a semiconductor package according to embodiments of the present invention.

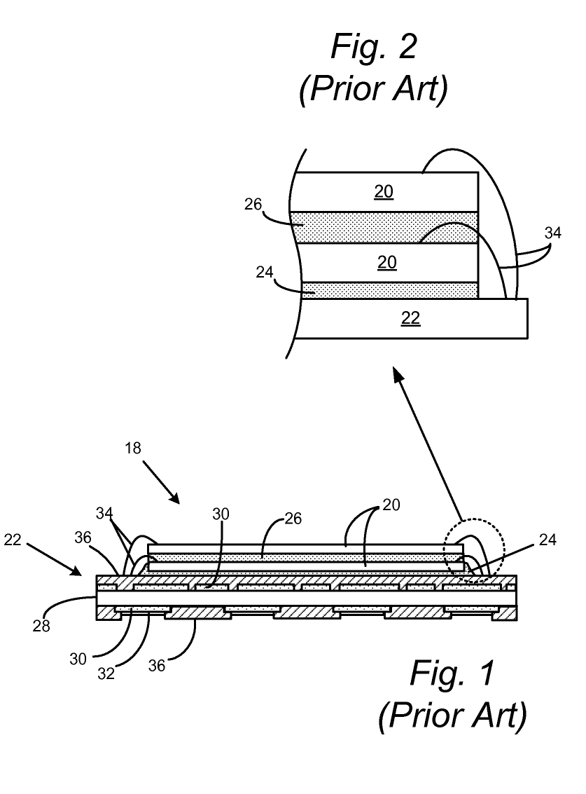

### DETAILED DESCRIPTION

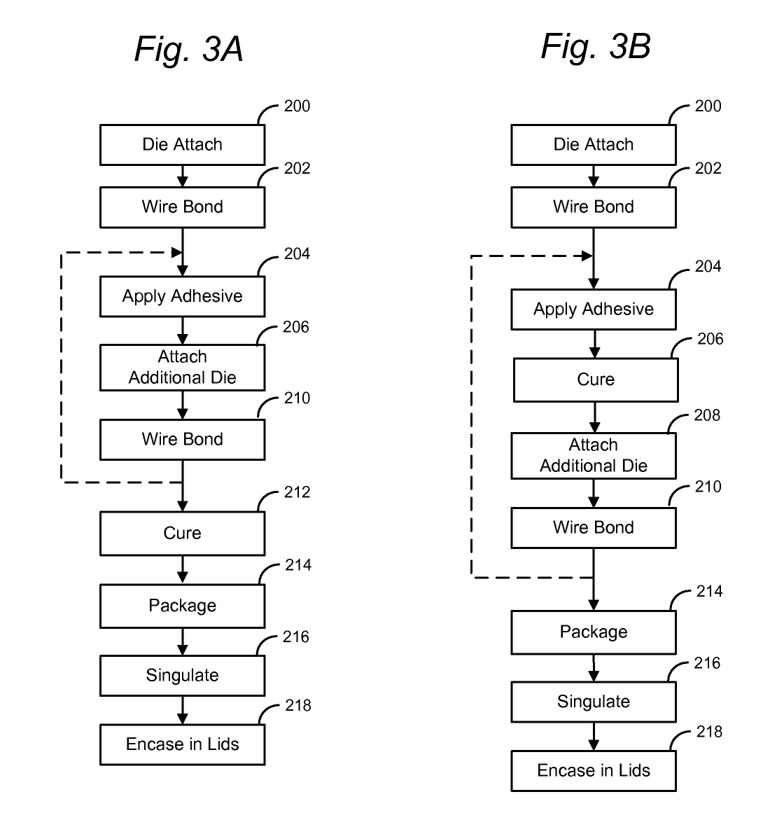

Embodiments will now be described with reference to FIGS. 3A through 13, which relate to a low profile semiconductor package. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

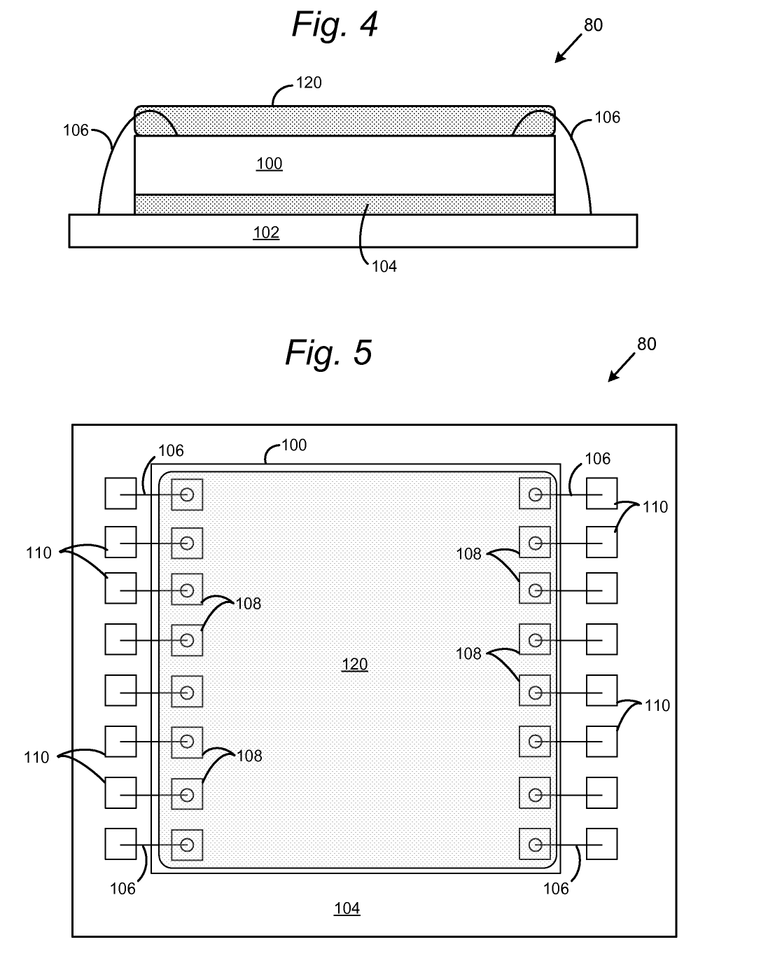

The present invention will now be described with reference to the flowchart of FIG. 3A and the side and top views shown in FIGS. 4-13. Embodiments of the present invention relate to a semiconductor package 80, a portion of which includes a first semiconductor die 100 mounted in step 200 to a substrate 102 as shown in FIGS. 4 and 5. The die 100 may be mounted to substrate 102 via a die attach adhesive layer 104 in a known adhesive or eutectic die bond process. The die attach adhesive layer 104 may for example be an epoxy of known construction available for example from Nitto Denko Corp. of Japan, Abelstik Co., California or Henkel Corporation, California. As explained hereinafter, the adhesive layer 104 may be applied as a viscous liquid, which remains in that state until cured in a reflow process.

Although not critical to the present invention, substrate 102 may be a variety of different chip carrier mediums, including a PCB, a leadframe or a tape automated bonded (TAB) tape. Where substrate 102 is a PCB, the substrate may be formed of a core having top and/or bottom conductive layers formed thereon. The core may be various dielectric materials such as for example, polyimide laminates, epoxy resins including FR4 and FR5, bismaleimide triazine (BT), and the like.

The conductive layers may be formed of copper or copper alloys, plated copper or plated copper alloys, Alloy 42 (42FE/58NI), copper plated steel or other metals or materials known for use on substrates. The conductive layers may be etched into a conductance pattern as is known for communicating signals between the semiconductor die and an external device. A dummy pattern may also be provided in the conductive layers as is known to reduce mechanical stresses on the substrate otherwise resulting from uneven thermal expansion within the substrate. Substrate 102 may additionally include exposed metal portions forming contact pads 110 (FIG. 5) and/or contact fingers (as in an example where the package 80 is a land grid array (LGA) package). The contact pads and/or fingers may be plated with one or more gold layers, for example in an electroplating process as is known in the art.

After semiconductor die 100 is affixed to substrate 102 in step 200, bond wires 106 may be attached between bond pads 108 (FIG. 5) on die 100 and bond pads 110 on substrate 102 in a step 202. Bond wires 106 may be affixed in a known wire bonding process. In embodiments, the wire bond process may be a low-profile wire bond process, such as for example a reverse bonding process. In the embodiments shown in FIGS. 4 and 5, wire bonds are provided along two opposed sides of die 100. In alternative embodiments of the present invention, wire bonds 106 may be provided along a single side, or three or four sides of die 100.

In step 204, an intermediate layer 120 may be applied onto the exposed surface of die 100. The intermediate layer 120 may for example be an electrically insulative adhesive epoxy of known composition available for example from Nitto Denko Corp. of Japan, Abelstik Co., California or Henkel Corporation, California. The intermediate layer 120 may be applied as a viscous liquid, which remains in that state until cured in a reflow process explained hereinafter. In embodiments, the intermediate layer 120 is applied as a liquid, but has a sufficiently high viscosity to mechanically support a second semiconductor die placed on layer 120 as explained hereinafter. In embodiments, the viscosity may be for example about 1-2×106 centipoise, but it is understood that the viscosity may be higher or lower than that in alternative embodiments. The intermediate layer 120 may be the same as or different from the material used as the adhesive layer 104. In an alternative embodiment, spacer balls may be provided within the intermediate layer 120. The spacer balls may be polymeric spheres that act as spacers between the die 100 and a second die mounted thereon as explained hereinafter. Such spacer balls are known in the art, and are disclosed for example in U.S. Pat. No. 6,650,019, entitled, “Method of Making a Semiconductor Package Including Stacked Semiconductor Die,” which patent is incorporated herein by reference in its entirety.

As seen in FIGS. 4 and 5, in an embodiment, the intermediate layer 120 may be applied over at least substantially the entire surface of die 100 (some of the edges may or may not be devoid of adhesive material). The adhesive material of layer 120 is applied such that the wire bond loops 106 are partially buried within the layer 120. Namely, the portion of bond wires 106 adjacent bond pads 108 as well as an apex of the bond loops are buried within intermediate layer 120. As intermediate layer 120 is applied only over the surface of die 100, portions of the wire 106 extending outside of the footprint of die 100 are not embedded within intermediate layer 120.

In addition to adhering the stacked semiconductor die together within the package 80, the intermediate layer 120 provides some spacing between the two stacked semiconductor die for location of the wire bond loops 106. However, no additional space in the intermediate layer is required to separate the wire bond loops 106 from a next adjacent semiconductor die. In particular, in the prior art, the adhesive layer in which the bond wires were embedded needed to be thick enough to ensure the bond wires would be prevented from shorting against the bottom surface of the next adjacent die. However, as explained in greater detail hereinafter, a surface of a second die affixed to the intermediate layer 120 is an electrical insulator. Accordingly, intermediate layer 120 need not space wire bond loops 106 from the next adjacent die as in the prior art, and the spacing between the stacked die may be made thinner in comparison to conventional stacked semiconductor die configurations. For example, the intermediate layer 120 may be between 25-50 microns (μm), as compared to about 75 μm in the prior art. It is understood that the thickness of the intermediate layer 120 may be less than 25 μm and greater than 50 μm in alternative embodiments of the present invention.

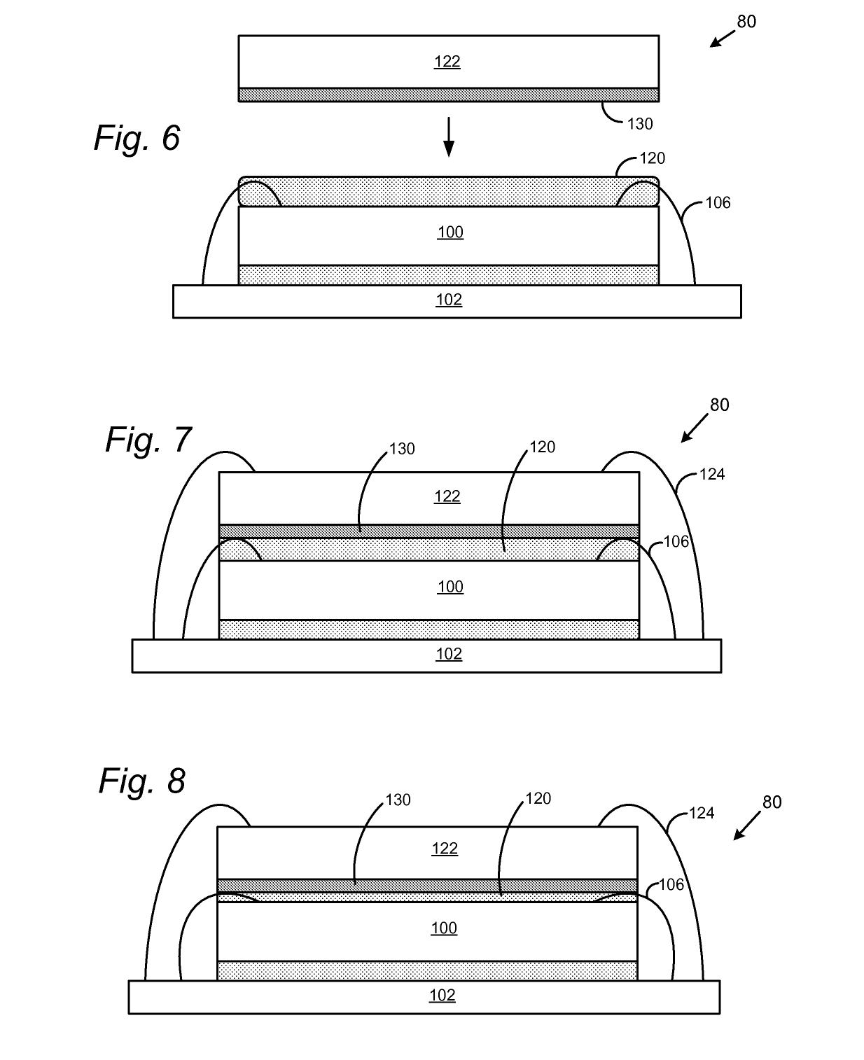

As indicated above, in step 206, a second semiconductor die 122 may be stacked on top of the intermediate layer 120 as shown in FIGS. 6 and 7. In accordance with the present invention, a dielectric layer 130 may be formed at the interface between semiconductor die 122 and intermediate layer 120. In embodiments, dielectric layer 130 may be formed on a back surface of semiconductor die 122. The dielectric layer 130 may be formed on semiconductor die 122 by any of a variety of known methods. In one embodiment, layer 130 may be an adhesive epoxy laminated onto the back side of semiconductor die 122 and cured before or with intermediate layer 120 as explained hereinafter. Dielectric layer 130 may alternatively be formed at the wafer level during fabrication of semiconductor die 122. For example, where the wafer is not background, the dielectric layer 130 may be grown during the semiconductor fabrication process. Dielectric layer 130 may further be formed by depositing a dielectric film on the back surface of semiconductor die 122 by a variety of processes including chemical plating, chemical vapor deposition, evaporation, sputtering, laser deposition, molecular beam epitaxy, spraying, painting or screen printing. Where the wafer is not background, the dielectric film may be deposited during wafer fabrication. Where a wafer is background, the dielectric film may be deposited after the backgrind process and prior to affixation of the die 122 to the intermediate layer 120. This may be before or after die 122 is singulated from the wafer. Other deposition techniques and other methods of forming dielectric layer 130 are contemplated. In embodiments, the dielectric layer 130 may be between 10 μm and 20 μm, though it is understood that the thickness of the dielectric layer 130 may be less than or greater than that in alternative embodiments of the present invention.

Once die 122 is affixed onto intermediate layer 120, die 122 may be wire bonded to substrate 102 in a step 210 using bond wires 124 in a known wire bond process.

Embodiments of the present invention may include only the pair of semiconductor die 100 and 122. However, in further embodiments, more than two semiconductor die may be stacked atop each other. In such embodiments, as indicated by the dashed arrow in FIG. 3A, steps 204 of applying an adhesive on the upper surface of the upper die, step 206 of attaching an additional die and step 210 of wire bonding the additional die may be repeated for each additional semiconductor die stacked on top of die 122.

As indicated above, intermediate layer 120 is applied with a viscosity sufficient to support semiconductor die 122 without excessively flattening wire bond loops 106. However, when semiconductor die 122 is attached to intermediate layer 120, pressure may be exerted on the intermediate layer so as to reduce the thickness of intermediate layer 120. In so doing, the apex of bond wires 106 may come into contact with dielectric layer 130 as shown in FIG. 7. However, as dielectric layer 130 electrically isolates each of the wire bonds 106 from each other and semiconductor die 122, no electrical short occurs.

In a further embodiment shown in FIG. 8, semiconductor die 122 may be affixed to package 140 under a compressive load so as to reduce a thickness of intermediate layer 120 as described above, as well as partially flattening the height of bond wires 106 above the surface of semiconductor 100. The thickness of layer 120 and the height of bonded wires 106 may be reduced an amount determined not to jeopardize the structural integrity of the wire bond connection to semiconductor die 100. As indicated above, in embodiments, this thickness may be between 25 and 50 μm, though it may be more or less than that in alternative embodiments.

Once all semiconductor die are affixed and wire bonded to substrate 102, the semiconductor package 80 may be cured in a reflow process of step 212 to harden each of the adhesive layers, including intermediate layer 120 and die attach layer 104. Curing may be accomplished by a variety of known methods, depending on the adhesive material used, including for example by heating and/or by ultraviolet radiation.

In the embodiment described above with respect to the flowchart of FIG. 3A, the package 80 is not cured until after all semiconductor die have been stacked and wire bonding has been completed. In an alternative embodiment of the present invention described with respect to the flowchart in FIG. 3B, the intermediate layer 120 and die bond layer 104 may be cured in step 206 prior to affixing the semiconductor die 122 (the layers 104 and 120 in this embodiment may either be cured at the same time or at different times in step 206). In such an embodiment, the dielectric layer 130 may be or include a curable adhesive so that semiconductor die 122 may be attached to cured intermediate layer 120 and thereafter firmly affixed, as in a subsequent curing process. It is further contemplated that die bond layer 104 and/or the intermediate layer 120 may be partially cured to a b-stage in step 206. The layers 104 and/or 106 may thereafter be fully cured after affixation of semiconductor die 122.

In embodiments described above, the intermediate layer 120 may be an adhesive material. However, it is understood that where the dielectric layer 130 is an adhesive, the intermediate layer 120 need not be an adhesive. In such an embodiment, the layer 120 may be applied as a liquid around bond wires 106 and act only as a spacer layer spacing the die 100 and 122 from each other and electrically isolating the bond wires 106 from each other. The die 100 and 122 in such an embodiment would be affixed to each other by the electrically insulative adhesive layer 130.

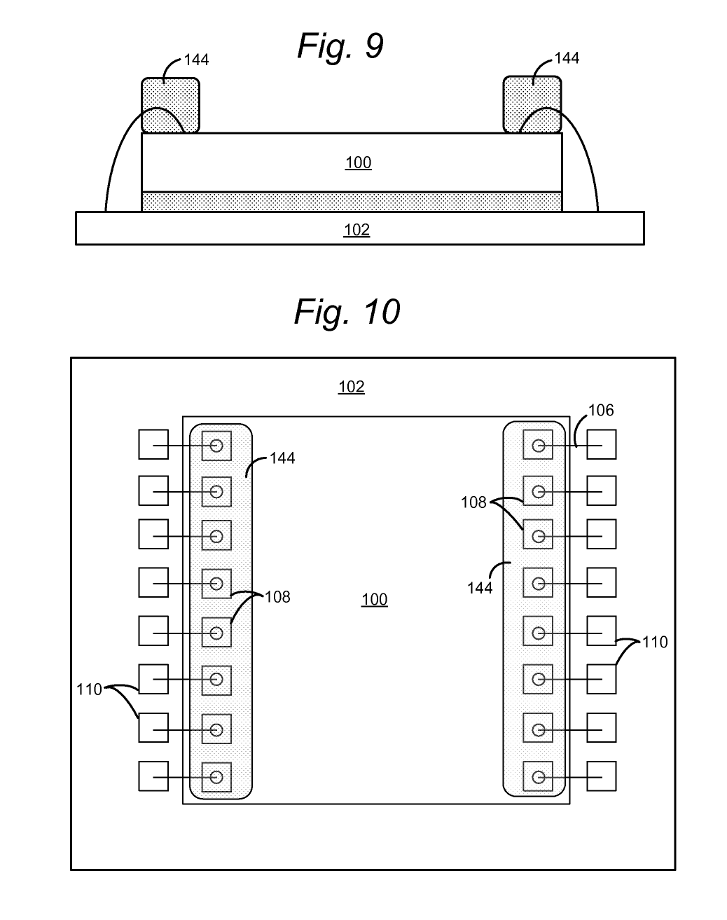

An alternative embodiment of the present invention is shown in FIGS. 9-12. In such an embodiment, instead of intermediate layer 120 being applied over substantially the entire surface of semiconductor die 100, the intermediate layer is applied as discrete quantities of adhesive material 144 only over and adjacent the contact pads 108 on semiconductor die 100. In particular, the adhesive material 144 may be applied to a first area on semiconductor die 100 including bond pads 108, and not applied to a second area on die 100 not including the bond pads. Such an embodiment may be used where there are one, two, three or four sides of contact pads 108 on semiconductor die 100.

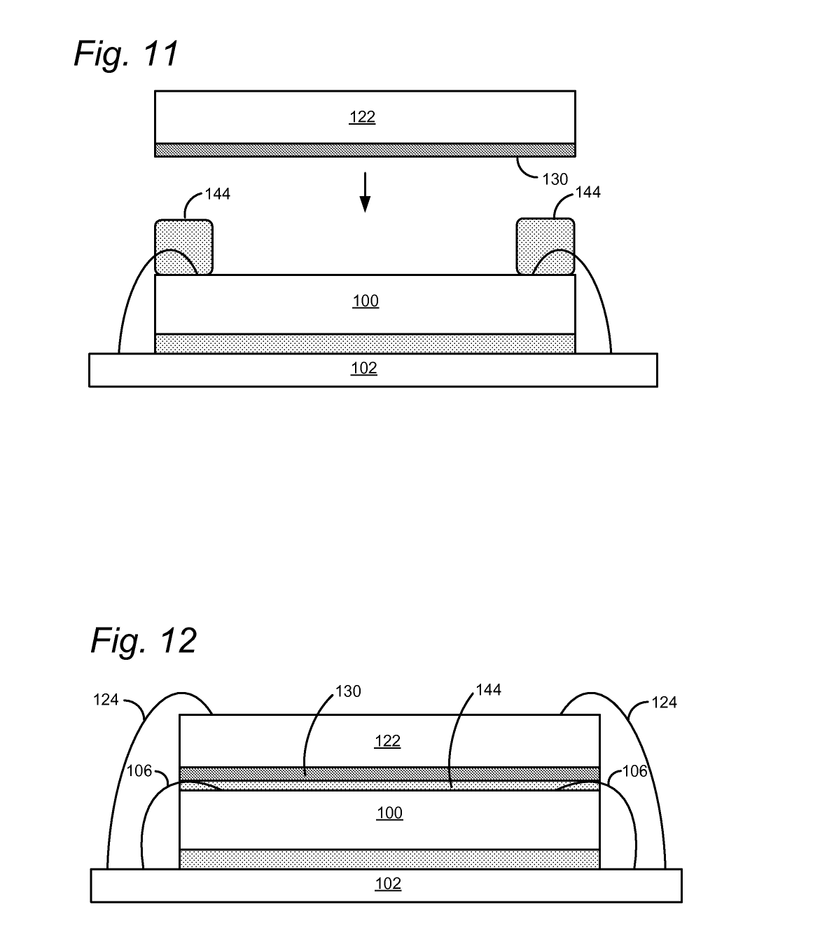

In this alternative embodiment, as indicated in FIGS. 11 and 12, when second semiconductor die 122 is affixed to the package, a compressive force may slightly flatten the adhesive 144. As indicated above, in addition to flattening adhesive 144, the compressive force may also reduce the height of the apex of the wire bond loop 106 above the surface of semiconductor die 100 Thereafter, during the curing process, the adhesive areas may further flatten and spread the adhesive 144 out across the surface of die 100. It is understood that liquid adhesive 144 may not entirely cover the surface of die 100 upon the attachment of die 122 and/or the subsequent curing process. Moreover, in embodiments where the dielectric layer 130 on semiconductor die 122 is also formed of a curable adhesive, both the adhesive material 144 and dielectric layer 130 may spread out across the interface between the die 100 and 122 to fill any space within the interface.

Once die 122 is affixed to the die 100 in the embodiment of FIGS. 9-12, the second semiconductor die 122 may be wire bonded to substrate 102 with wire bonds 124 in a known wire bond process. The package may then be cured as described above.

In the above-described embodiments, the bond wires from die 100 and 122 may be uncoated gold, though it may alternatively be copper, aluminum or other metals. In a further embodiment of the present invention, the bond wires from die 100 and/or 122 may be pre-insulated (i.e., prior to be immersed in intermediate layer 120) with polymeric insulation that makes the surface of the wire electrically non-conductive. Such pre-insulated bond wire is known for preventing shorting between adjacent bond wires. Two examples of a pre-insulated bond wire which is suitable for use in the present invention are disclosed in U.S. Pat. No. 5,396,104, entitled, “Resin Coated Bonding Wire, Method of Manufacturing the Same, and Semiconductor Device,” and U.S. Published Patent Application No. 2004/0124545, entitled, “High Density Integrated Circuits and the Method of Packaging the Same,” both of which are incorporated by reference herein in their entirety. An embodiment utilizing a pre-insulated bond wire may operate with or without intermediate layer 120. In such an embodiment operating without intermediate layer 120, the dielectric layer 130 may be an adhesive for affixing the die together.

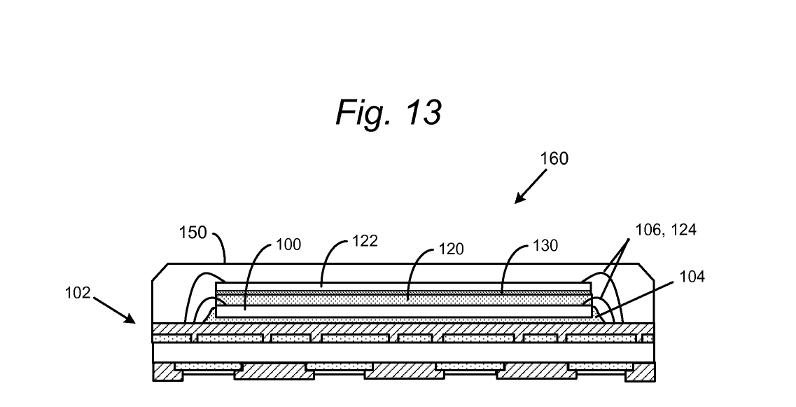

As shown in FIG. 13, after forming the stacked die configuration according to any of the above described embodiments, the configuration may be encased within the molding compound 150 in step 214, and singulated in step 216, to form a finished semiconductor die package 160. Molding compound 150 may be a known epoxy such as for example available from Sumitomo Corp. and Nitto Denko Corp., both having headquarters in Japan. Thereafter, the finished package 160 may optionally be enclosed within a lid in step 218.

In embodiments, the semiconductor die described above may include one or more flash memory chips, and possibly a controller such as an ASIC, so that the package 160 may be used as a flash memory device. It is understood that the package 160 may include semiconductor die configured to perform other functions in further embodiments of the present invention.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

1.-19. (canceled)

20. A method of forming a semiconductor device including first and second stacked semiconductor die, the method comprising the steps of:
(a) wire bonding a plurality of wires to a surface of the first semiconductor die to form a plurality of wire bond loops;
(b) embedding a portion of each wire bond loop of the plurality of wire bond loops within an intermediate layer applied onto the surface of the first semiconductor die;
(c) forming an electrical insulator on a surface of the second semiconductor die; and
(d) affixing the second semiconductor die to the first semiconductor die with the electrical insulator interposed between the intermediate layer and the second semiconductor die.

21. A method as recited in claim 20, wherein said step (b) of embedding a portion of each wire bond loop of the plurality of wire bond loops within the intermediate layer applied onto the surface of the first semiconductor die comprises the step of covering at least substantially all of the first surface of the first semiconductor die with a liquid.

22. A method as recited in claim 20, wherein said step (b) of embedding a portion of each wire bond loop of the plurality of wire bond loops within the intermediate layer applied onto the surface of the first semiconductor die comprises the step of covering a first area of the surface including the wire bond loops and not covering a second area of the surface not including the wire bond loops.

23. A method as recited in claim 20, wherein said step (b) of embedding a portion of each wire bond loop of the plurality of wire bond loops within the intermediate layer comprises the step of applying a liquid onto the surface of the first semiconductor die around portions of each wire bond loop.

24. A method as recited in claim 23, wherein said step (b) of applying a liquid onto the surface of the first semiconductor die comprises the step of applying a liquid epoxy to the surface of the first semiconductor die.

25. A method as recited in claim 23, further comprising the step (c) of hardening the intermediate layer.

26. A method as recited in claim 25, wherein said step (e) of hardening the intermediate layer comprises the step of curing the intermediate layer.

27. A method as recited in claim 25, wherein said step (e) of hardening the intermediate layer occurs after said step (d) of affixing the second semiconductor die to the first semiconductor die.

28. A method as recited in claim 27, wherein said step (d) of affixing the second semiconductor die to the first semiconductor die comprises reducing a thickness of the intermediate layer under a compressive force exerted on the intermediate layer by the first and second semiconductor die.

29. A method as recited in claim 27, wherein said step (d) of affixing the second semiconductor die to the first semiconductor die comprises reducing a height of the wire bond loops within the intermediate layer under a compressive force exerted on the intermediate layer by the first and second semiconductor die.

30. A method as recited in claim 25, wherein said step (e) of hardening the intermediate layer occurs before said step (d) of affixing the second semiconductor die to the first semiconductor die.

31. A method as recited in claim 20, wherein said step (c) of forming an electrical insulator on a surface of the second semiconductor die comprises the step of laminating a dielectric film on the surface of the second semiconductor die.

32. A method as recited in claim 20, wherein said step (c) of forming an electrical insulator on a surface of the second semiconductor die comprises the step of oxidizing the surface of the second semiconductor die during fabrication of the semiconductor die.

33. A method as recited in claim 20, wherein said step (c) of forming an electrical insulator on a surface of the second semiconductor die comprises the step of spin-coating a dielectric material on the surface of the second semiconductor die.

34. A method as recited in claim 20, wherein said step (c) of forming an electrical insulator on a surface of the second semiconductor die comprises the step of depositing a dielectric material in a thin film deposition process.

35. A method as recited in claim 20, wherein said step (c) of forming an electrical insulator on a surface of the second semiconductor die comprises the step of a chemical reaction on a backside of a wafer including the second semiconductor die making the backside of the wafer insulative.

36. A method of forming a semiconductor device including first and second stacked semiconductor die, the method comprising the steps of:
(e) wire bonding a plurality of wires to a surface of the first semiconductor die to form a plurality of wire bond loops;
(f) embedding a portion of each wire bond loop of the plurality of wire bond loops within an intermediate layer applied onto the surface of the first semiconductor die;
(g) affixing the second semiconductor die to the first semiconductor die; and
(h) electrically isolating the second semiconductor die from the intermediate layer.

37. A method as recited in claim 36, wherein said step (d) of electrically isolating the second semiconductor die from the intermediate layer comprises the step of laminating a dielectric film on the surface of the second semiconductor die.

38. A method as recited in claim 36, wherein said step (d) of electrically isolating the second semiconductor die from the intermediate layer comprises the step of oxidizing the surface of the second semiconductor die during fabrication of the semiconductor die.

39. A method as recited in claim 36, wherein said step (d) of electrically isolating the second semiconductor die from the intermediate layer comprises the step of spin-coating a dielectric material on the surface of the second semiconductor die.

40. A method as recited in claim 36, wherein said step (d) of electrically isolating the second semiconductor die from the intermediate layer comprises the step of depositing a dielectric material in a thin film deposition process.
